(19) United States
(12) Patent Application Publication
(10) Pub. No.: US 2006/0043363 A1
(43) Pub. Date: Mar. 2, 2006

(54) Vertical organic FET and method for manufacturing same

(75) Inventor: Akihito Miyamoto, Osaka (JP)

Correspondence Address: McDERMOTT WILL & EMERY LLP, 600 13th Street, N.W., Washington, DC, 20005-3096, US

(73) Assignee: MATSUSHITA ELECTRIC INDUSTRIAL CO., LTD., Osaka (JP)

(21) Appl. No.: 11/260,186

(22) Filed: Oct. 28, 2005

Related U.S. Application Data
(63) Continuation of application No. PCT/JP04/12413, filed on Aug. 22, 2003.

(30) Foreign Application Priority Data
Aug. 22, 2003 (JP) 2003-298455

(51) Int. Cl. H01L 29/08

(52) U.S. Cl. 257/40

(57) ABSTRACT

The present invention provides a vertical organic FET with increased carrier mobility and suppressed molecular orientation of an active layer composed of an organic semiconductor. The present invention relates to a vertical organic FET having a structure in which at least a source electrode layer, a drain electrode layer, a gate electrode, and an active layer are provided on a substrate, and the source electrode layer, the active layer, and the drain electrode layer are laminated in that order, wherein (1) the source electrode layer and the drain electrode layer are disposed substantially parallel to the substrate plane, (2) the source electrode layer and the drain electrode layer are electroconductive members, (3) the active layer is substantially constituted by a phthalocyanine compound that has a tetravalent or hexavalent element as its central atom and in which ligands X₁ and X₂ coordinate up and down, respectively, from the molecular plane, and (4) the compound is layered such that the molecular plane of each molecule of the compound is in a substantially parallel state with respect to the source electrode layer and/or the drain electrode layer.

### FIELD OF THE INVENTION

This invention relates to a novel vertical organic FET and a method for manufacturing the same.

### BACKGROUND OF THE INVENTION

Recent years have seen research into the use of organic semiconductor materials as active layers in a variety of devices, such as light emitting diodes, non-linear optical devices, and field effect transistors.

Because they lend themselves so well to being worked, organic semiconductor materials allow for simpler and lower cost manufacturing equipment. Another advantage of organic semiconductor materials is that they can be laminated more easily than amorphous silicon or the like on a flexible plastic substrate.

Most of the research conducted in the past into FETs made from organic semiconductor materials related to horizontal types. In these types, a gate electrode and an insulating layer are provided on a substrate, source and drain metal electrodes are disposed on top of the insulating layer, and an organic semiconductor material that serves as an active layer is formed by vapor deposition, spin coating, or another such method. These devices control the flow of current between the source and drain by controlling the gate voltage. However, organic semiconductors have high electrical resistance and low carrier mobility, so their drawbacks include the inability to carry a large current and slow operation.

In view of this, Kudo et al. have recently proposed a vertical organic FET having a buried gate transistor structure known as a static induction transistor (SIT) (Synthetic Materials, 102 (1990), 900). A method for manufacturing this device has also been proposed (Japanese Patent No. 3,403,136).

One organic semiconductor device that has been proposed is a device comprising a lower electrode, a vapor-deposited lead phthalocyanine film, and an upper electrode formed in that order on a substrate (Japanese Published Patent Application S63-244678).

Further, it has been proposed that a semiconductor apparatus in which a first electrode layer, a semiconductor layer, and a second electrode layer are laminated in that order, wherein a first electrical insulating layer and then a third electrical insulating layer are provided vertically so as to be in contact with one of the side walls of these layers, be used as a vertical field effect transistor (Japanese Published Patent Application 2003-110110).

An advantage to these vertical organic FETs is that since the lengthwise direction of the channel between the source and drain is the film thickness direction, the channel can be shorter than with a horizontal configuration. This greatly enhances the device characteristics, such as operating speed. Also, since light emitting materials used for organic electroluminescence and so forth can be laminated, a flexible device can be manufactured easily and at low cost.

### DISCLOSURE OF THE INVENTION

When the characteristics of a vertical organic FET are to be further enhanced, the molecular orientation of the active layer composed of an organic semiconductor becomes very important. For example, when a film of a phthalocyanine material is produced by vapor deposition, the molecules are usually oriented (grow) parallel to the substrate, so with a horizontal FET, overlapping π electrons can be formed between the source and drain, and a conductive channel can be formed and controlled with a gate electrode.

However, if a horizontal type is merely turned around into vertical type, since the molecular orientation is parallel to the substrate as mentioned above, or in other words, is perpendicular to a straight line connecting the source and drain, this structure leads to lower carrier mobility and slower operation than with a vertical organic FET. This situation needs to be remedied.

Therefore, a main object of the present invention is to provide a vertical organic FET having excellent carrier mobility, operating speed, and so forth.

Specifically, the present invention relates to the following vertical organic FET and a method for manufacturing the same.

1. A vertical organic FET having a structure in which at least a source electrode layer, a drain electrode layer, a gate electrode, and an active layer are provided on a substrate, and the source electrode layer, the active layer, and the drain electrode layer are laminated in that order, wherein:

(1) the source electrode layer and the drain electrode layer are disposed substantially parallel to the substrate plane;

(2) the source electrode layer and the drain electrode layer comprises conductive material, respectively;

(3) the active layer is substantially constituted by a phthalocyanine compound that has a tetravalent or hexavalent element as its central atom and has ligands X₁ and X₂, respectively, below and above the plane of the molecular of the compound which coordinate to the central atom; and

(4) the compound is layered so that the plane of each molecule of the compound is in a substantially parallel state with respect to the source electrode layer and/or the drain electrode layer.

2. The vertical organic FET according to above 1, wherein the compound is layered so that, as the parallel state, the angle formed by the molecular plane and the substrate plane is in the range of no less than 0 degrees but no more than 45 degrees.

3. The vertical organic FET according to above 1, wherein, in an X-ray diffraction pattern obtained by analyzing the active layer with X-ray diffraction using a Cu—Kα radiation, the diffraction peak having the greatest intensity appears in the region where the Bragg angle (2 θ) is at least 20°.

4. The vertical organic FET according to above 1, wherein, in an X-ray diffraction pattern obtained by analyzing the active layer with X-ray diffraction using a Cu—Kα radiation, the diffraction peak having the greatest intensity appears in the region where the Bragg angle (2 θ) is no less than 25.5° but no more than 27.5°.

5. The vertical organic FET according to above 1, wherein the central atom is a tetravalent element.

6. The vertical organic FET according to above 1, wherein the central atom is Si, Ge, or Sn.

7. The vertical organic FET according to above 1, wherein the phthalocyanine compound is represented by the following general formula: 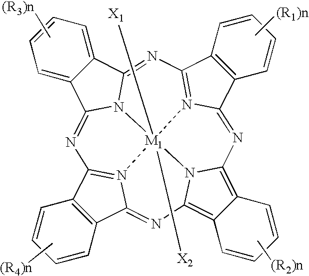
wherein R₁ to R₄ may be the same or different, and are each a hydrogen or a substituent; n is the number of substituents; M1 is Si, Ge, or Sn; X₁ and X₂ may be the same or different, and are each a halogen, phenyl group, or C₅ or lower alkyl group.

8. The vertical organic FET according to above 1, wherein the conductive material is at least one type selected from among metals, metal oxides, and silicon.

9. The vertical organic FET according to above 1, wherein an insulating layer is provided on a side of the laminate composed of the source electrode layer, the drain electrode layer, and the active layer so as to be in contact with these three layers, and the gate electrode is formed so as to be insulated from the three layers by the insulating layer.

10. The vertical organic FET according to above 1, wherein the active layer and the gate electrode are interposed between the source electrode layer and the drain electrode layer, and the active layer and gate electrode are provided so as to be in contact with each other.

11. A vertical organic FET having a structure in which at least a source electrode layer, a drain electrode layer, a gate electrode, and an active layer are provided on a substrate, and the source electrode layer, the active layer, and the drain electrode layer are laminated in that order, wherein:

(1) the source electrode layer and the drain electrode layer are disposed substantially parallel to the substrate plane;

(2) the source electrode layer and the drain electrode layer comprises conductive material, respectively;

(3) the active layer is substantially constituted by a phthalocyanine compound that has a tetravalent or hexavalent element as its central atom and has ligands X₁ and X₂, respectively, below and above the plane of the molecular of the compound which coordinate to the central atom; and

(4) in an X-ray diffraction pattern obtained by analyzing the active layer with X-ray diffraction using a Cu—Kα radiation, the diffraction peak having the greatest intensity appears in the region where the Bragg angle (2 θ) is at least 20°.

12. The vertical organic FET according to above 11, wherein the diffraction peak appears in the region where the Bragg angle (2 θ) is no less than 25.5° but no more than 27.5° C.

13. The vertical organic FET according to above 11, wherein the central atom is a tetravalent element.

14. The vertical organic FET according to above 11, wherein the central atom is Si, Ge, or Sn.

15. The vertical organic FET according to above 11, wherein the phthalocyanine compound is represented by the following general formula: 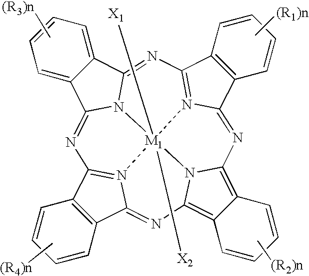
wherein R₁ to R₄ may be the same or different, and are each a hydrogen or a substituent; n is the number of substituents; M1 is Si, Ge, or Sn; X₁ and X₂ may be the same or different, and are each a halogen, phenyl group, or C₅ or lower alkyl group.

16. The vertical organic FET according to above 11, wherein the conductive material is at least one type selected from among metals, metal oxides, and silicon.

17. The vertical organic FET according to above 11, wherein an insulating layer is provided on a side of the laminate composed of the source electrode layer, the drain electrode layer, and the active layer so as to be in contact with these three layers, and the gate electrode is formed so as to be insulated from the three layers by the insulating layer.

18. The vertical organic FET according to above 11, wherein the active layer and the gate electrode are interposed between the source electrode layer and the drain electrode layer, and the active layer and gate electrode are provided so as to be in contact with each other.

19. A method for manufacturing a vertical organic FET in which a source electrode layer, a drain electrode layer, a gate electrode, and an active layer are provided on a substrate,

comprising a step of forming the active layer by using a phthalocyanine compound that has a tetravalent or hexavalent element as its central atom and has ligands X₁ and X₂, respectively, below and above the plane of the molecular of the compound which coordinate to the central atom.

20. The manufacturing method according to above 19, wherein the central atom is a tetravalent element.

21. The manufacturing method according to above 19, wherein the central atom is Si, Ge, or Sn.

22. The manufacturing method according to above 19, wherein the phthalocyanine compound is represented by the following general formula: 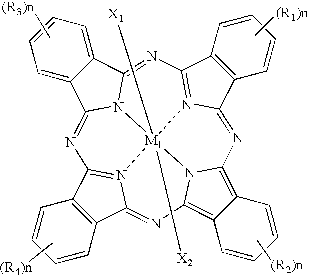
wherein R₁ to R₄ may be the same or different, and are each a hydrogen or a substituent; n is the number of substituents; M₁ is Si, Ge, or Sn; X₁ and X₂ may be the same or different, and are each a halogen, phenyl group, or C₅ or lower alkyl group.

23. The manufacturing method according to above 19, wherein the active layer is formed by vapor phase process using the phthalocyanine compound.

24. The manufacturing method according to above 19, wherein the vertical organic FET is one having a structure in which at least a source electrode layer, a drain electrode layer, a gate electrode, and an active layer are provided on a substrate, and the source electrode layer, the active layer, and the drain electrode layer are laminated in that order, wherein:

(1) the source electrode layer and the drain electrode layer are disposed substantially parallel to the substrate plane;

(2) the source electrode layer and the drain electrode layer comprises conductive material, respectively;

(3) the active layer is substantially constituted by a phthalocyanine compound that has a tetravalent or hexavalent element as its central atom and has ligands X₁ and X₂, respectively, below and above the plane of the molecular of the compound which coordinate to the central atom; and

(4) the compound is layered so that the plane of each molecule of the compound is in a substantially parallel state with respect to the source electrode layer and/or the drain electrode layer.

25. The manufacturing method according to above 19, wherein the vertical organic FET is one having a structure in which at least a source electrode layer, a drain electrode layer, a gate electrode, and an active layer are provided on a substrate, and the source electrode layer, the active layer, and the drain electrode layer are laminated in that order, wherein:

(1) the source electrode layer and the drain electrode layer are disposed substantially parallel to the substrate plane;

(2) the source electrode layer and the drain electrode layer comprises conductive material, respectively;

(3) the active layer is substantially constituted by a phthalocyanine compound that has a tetravalent or hexavalent element as its central atom and has ligands X₁ and X₂, respectively, below and above the plane of the molecular of the compound which coordinate to the central atom; and

(4) in an X-ray diffraction pattern obtained by analyzing the active layer with X-ray diffraction using a Cu—Kα radiation, the diffraction peak having the greatest intensity appears in the region where the Bragg angle (2 θ) is at least 20°.

### BRIEF DESCRIPTION OF THE DRAWINGS

FIG. 1 is a schematic cross section of a vertical organic FET pertaining to an embodiment of the present invention;

FIG. 2 consists of schematics of the molecular orientation pertaining to an embodiment of the present invention, with FIG. 2(a) being a schematic of when the molecular plane is substantially perpendicular to the substrate, and FIG. 2(b) a schematic of when the molecular plane is substantially parallel to the substrate as in the present invention;

FIG. 3 is a graph of an X-ray diffraction pattern profile featuring the CuKα radiation of an SnCl₂-Pc thin film;

FIG. 4 is a graph of an X-ray diffraction pattern profile featuring the CuKα radiation of a CuPc thin film;

FIG. 5 is a schematic cross section of of the insulating gate type structure of a vertical organic FET pertaining to an embodiment of the present invention; and

FIG. 6 consists of schematics of the molecular orientation pertaining to an embodiment of the present invention, with FIG. 6(a) being a schematic of the structure of the vertical organic FET as viewed from above, and FIG. 6(b) a schematic of the cross sectional structure of the vertical organic FET.

### LIST OF ELEMENTS

1 substrate
2 source electrode layer
3 drain electrode layer
4 gate electrode
5 active layer
6 protective layer
7 insulating layer
10 substrate
20 source electrode layer
30 drain electrode layer
40 gate electrode
50 active layer

### BEST MODE FOR CARRYING OUT THE INVENTION

1. Vertical Organic FET

The vertical organic FET of the present invention is one having a structure in which at least a source electrode layer, a drain electrode layer, a gate electrode, and an active layer are provided on a substrate, and the source electrode layer, the active layer, and the drain electrode layer are laminated in that order, wherein:

(1) the source electrode layer and the drain electrode layer are disposed substantially parallel to the substrate plane;

(2) the source electrode layer and the drain electrode layer comprises conductive material, respectively;

(3) the active layer is substantially constituted by a phthalocyanine compound that has a tetravalent or hexavalent element as its central atom and has ligands X₁ and X₂, respectively, below and above the plane of the molecular of the compound which coordinate to the central atom; and

(4) the compound is layered so that the plane of each molecule of the compound is in a substantially parallel state with respect to the source electrode layer and/or the drain electrode layer.

The basic structure of the vertical organic FET of the present invention is such that at least a source electrode layer, a drain electrode layer, a gate electrode, and an active layer are provided on a substrate. There are no particular restrictions on the layout of these components, as long as they are disposed in the order of the source electrode layer, the active layer, and the drain electrode layer. For example, the layout may be either substrate/source electrode layer/active layer/drain electrode layer, or substrate/drain electrode layer/active layer/source electrode layer.

With the vertical organic FET of the present invention, the source electrode layer and the drain electrode layer are disposed substantially parallel to the substrate plane. Put another way, the design is such that the current flowing through the source electrode layer and drain electrode layer flows perpendicular to the substrate plane.

There are no restrictions on the shape, layout, etc., of the gate electrodes 4, which can be suitably determined according to the type of FET. In particular, the vertical organic FET in the present invention can be either a Schottky gate type or an insulated gate type. Therefore, the gate electrodes 4 may be provided perpendicular to the substrate plane, or a sheet-form gate electrode in which holes have been made in the form of a mesh may be inserted in the active layer.

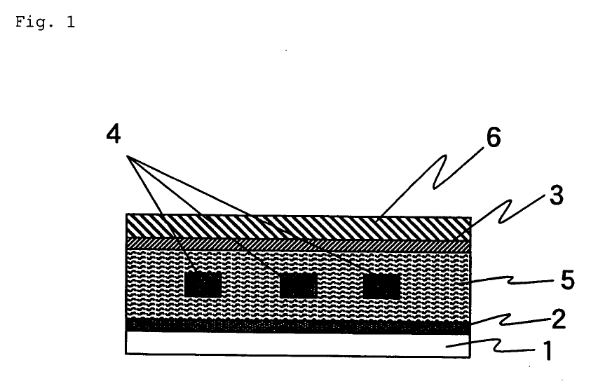

More specifically, as shown in FIG. 1, a Schottky gate type comprises gate electrodes 4 and an active layer 5 jointed by Schottky junction. In FIG. 1, there is a pair of electrode layers comprising a source electrode layer 2 and a drain electrode layer 3 on the top part of a substrate 1, and the gate electrodes 4 and the active layer 5 are interposed therebetween. A protective layer 6 may be provided over the top of this. It is particularly favorable for the source electrode layer 2 and the drain electrode layer 3 to be disposed substantially parallel to the substrate 1 as shown in FIG. 1.

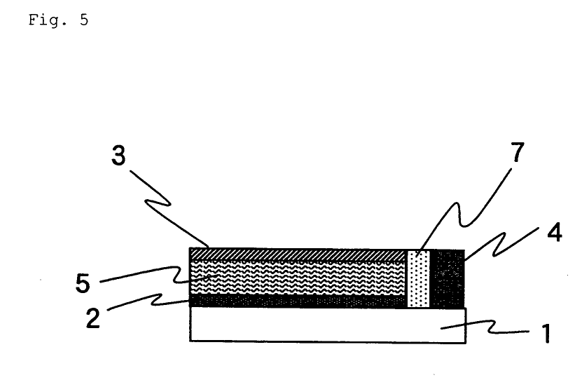

As shown in FIG. 5, an insulating gate type comprises a source electrode layer 2, an active layer 5, and a drain electrode layer 3 laminated in that order on the top part of a substrate 1, and an insulating layer 7 provided in contact with the side walls of the above, and a gate electrode 4 is provided to the side wall of the insulating layer 7. Here again, as shown in FIG. 5, it is preferable for the source electrode layer 2 and the drain electrode layer 3 to be disposed substantially parallel to the substrate 1.

Examples of the material of the substrate 1 include undoped silicon, highly-doped silicon, glass, acrylic resins, polycarbonate resins, polyamide resins, polystyrene resins, and polyester resins, which may be suitably selected according to the intended usage.

There are no limitations on the material used for the source electrode layer 2, the drain electrode layer 3, and the gate electrode 4, but electroconductive material can be used to particular advantage. Examples include gold, silver, copper, platinum, aluminum, chromium, titanium, molybdenum, magnesium, lithium, palladium, cobalt, tin, nickel, indium, tungsten, ruthenium, and other such metals. These can be used singly or in combinations of two or more (as alloys, for example). Other possibilities include polysilicon, amorphous silicon, and other forms of silicon, and tin oxide, indium oxide, tin oxide, and other such metal oxides.

The thickness of these electrodes 2 to 4 can be suitably set as dictated by the desired characteristics of the vertical organic FET and so forth, but generally a range of at least 10 nm and no more than 200 nm is preferred. It is generally preferable for the thickness of the insulating layer that is provided as needed to be at least 10 nm and no more than 200 nm. The thickness of the protective layer is preferably at least 100 nm and no more than 10 μm.

The active layer 5 is substantially constituted by a phthalocyanine compound that has a tetravalent or hexavalent element as its central atom and has ligands X₁ and X₂, respectively, below and above the plane of the molecular of the compound which coordinate to the central atom. Specifically, the active layer is formed from a compound (complex) in which two halogen atoms at the center part of phthalocyanine have been replaced with the above-mentioned atoms, and two ligands coordinate.

Examples of tetravalent elements include Si, Ge, Sn, Pb, Pd, Ti, Mn, Tc, Ir, and Rh. Examples of hexavalent elements include Mn, Re, Cr, Mo, W, and Te. Of these elements, a tetravalent element is preferred. Si, Ge, or Sn is particularly favorable.

There are no particular restrictions on the ligands X₁ and X₂ as long as the parallel state mentioned in (4) above can be maintained, but examples include halogens (eg, F, Cl, Br, I), phenyl groups, alkyl groups (eg, a methyl group or ethyl group), carbonyl (CO), cyano (CN), and ammine (NH₃). Of these, a halogen, phenyl group, or C₅ or lower alkyl group is preferred. X₁ and X₂ may be the same as or different from each other.

The above-mentioned phthalocyanine compound is a complex having a porphyrin structure, with no restrictions thereon as long as it has one of the above-mentioned elements at its center. For example, a compound represented by the following general formula can be used favorably as an organic semiconductor.

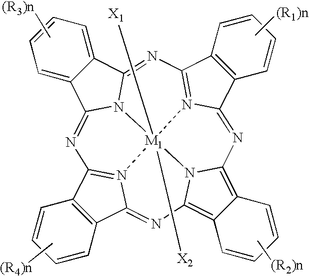

Here, R₁ to R₄ may be the same or different, and are each a hydrogen or a substituent; n is the number of substituents; M1 is Si, Ge, or Sn; and X₁ and X₂ may be the same or different, and are each a halogen, phenyl group, or C₅ or lower alkyl group.

There are no restrictions on the above-mentioned substituent as long as it is capable of forming a laminated structure such as that discussed below, and can be suitably selected from among electron attractive groups and electron donor groups. Examples include a linear or branched alkyl group (eg, methyl group, ethyl group, propyl group, and butyl group), alkynyl group, alkenyl group, substitutable aryl group, allyl group, alkoxy group (eg, methoxy group and ethoxy group), alkoxycarbonyl group, hydroxy group, carboxyl group, alkyloxy group, aryloxy group, alkylthio group, arylthio group, nitro group, amino group, amide group, aminoalkyl group, cyano group, cyanoalkyl group, substitutable three-member or higher heterocyclic group, phenyl group, halogen, and mercapto group or the like.

A hydrogen or a C₅ or lower alkyl group is particularly favorable as R₁ to R₄ in the present invention.

The substitution number n is generally an integer of at least 0 and no more than 4. M1 is Si, Ge, or Sn. X₁ and X₂ may be the same or different, and are each a halogen, phenyl group, or C₅ or lower alkyl group.

These phthalocyanine compounds can be used singly or in combinations of two or more. Using a single type is preferable in terms of the orientation of the molecular plane. Phthalocyanine is sometimes abbreviated as “Pc” in this Specification.

The active layer is layered such that the molecular plane of each molecule of the compound is in a substantially parallel state with respect to the source electrode layer and/or the drain electrode layer. It is particularly favorable for the substrate plane, the source electrode layer, and the drain electrode layer to be substantially parallel to each other, and for these and the above-mentioned molecular plane to be maintained in a parallel state.

The “parallel state” referred to in the present invention means that the angle formed by the molecular plane and the source electrode layer and/or the drain electrode layer is in the range of at least 0 degrees and no more than 45 degrees (and preferably at least 0 degrees and no more than 21 degrees).

The above-mentioned angle may be the one formed either clockwise or counter-clockwise from the source electrode layer and/or the drain electrode layer. In other words, the above-mentioned angle may be at least ±0 degrees and no more than ±45 degrees, and preferably at least ±0 degrees and no more than ±21 degrees.

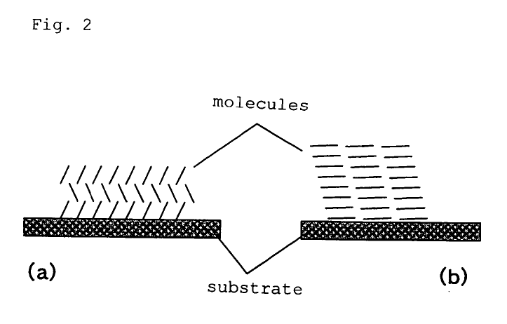

FIG. 2 illustrates the orientation of the molecules with respect to the substrate. FIG. 2(a) shows the state when the molecular plane is disposed (laminated) substantially perpendicular to the substrate plane, and FIG. 2(b) shows the state when the molecular plane is laminated in a parallel state with respect to the substrate plane (present invention).

FIG. 2 shows the positional relationship of the molecules with respect to the substrate plane, but also applies to the positional relationship between the molecular plane and the source electrode layer and/or the drain electrode layer (the same applies hereinafter).

With the present invention, it can be confirmed by X-ray diffraction whether or not the molecular plane is in a parallel state with respect to the substrate plane or the source electrode layer and/or the drain electrode layer. Specifically, in an X-ray diffraction pattern obtained by analyzing the active layer with X-ray diffraction using a Cu—Kα radiation, the diffraction peak having the greatest intensity appears in the region where the Bragg angle (2 θ) is at least 20° (and preferably at least 25.5° and no more than 27.5°).

For example, the molecular orientation of a thin film produced by forming a phthalocyanine compound such as copper phthalocyanine (CuPc) on a substrate is usually such that the molecular plane is oriented substantially perpendicular to the substrate plane, and the X-ray diffraction pattern reveals a strong diffraction peak at a low angle (2 θ≦10°). The interplanar spacing d derived from this is 1.00 to 1.34 nm. Specifically, since the diameter of a phthalocyanine molecule is approximately 1.34 nm, we know that the molecular plane is oriented substantially perpendicular to the substrate plane.

In contrast, with the phthalocyanine compound of the present invention, a diffraction peak is observed at a position where the Bragg angle (2 θ) in X-ray diffraction pattern with a CuKα radiation is from 25.5° to 27.5°, so the interplanar spacing (d) of the molecules is approximately 0.32 to 0.35 nm. This tells us that the molecular plane of the phthalocyanine molecules is not oriented perpendicular to the substrate plane, but rather is substantially parallel (the angle formed by the substrate plane and the molecular plane is at least 0 degrees and no more than 45 degrees). This makes possible a molecular orientation in which the overlapping of z electrons occurs perpendicular to the substrate plane, and as a result a vertical organic FET that exhibits good carrier mobility and so forth can be provided.

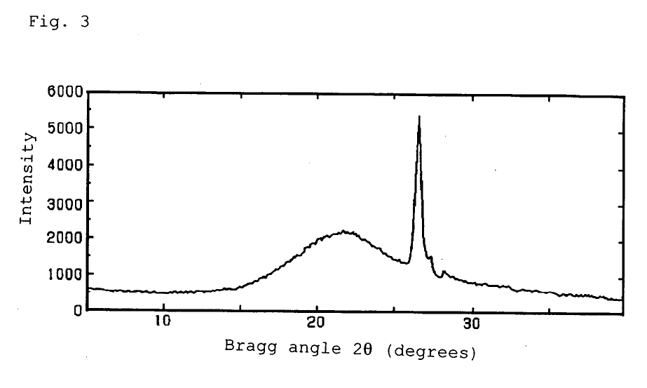

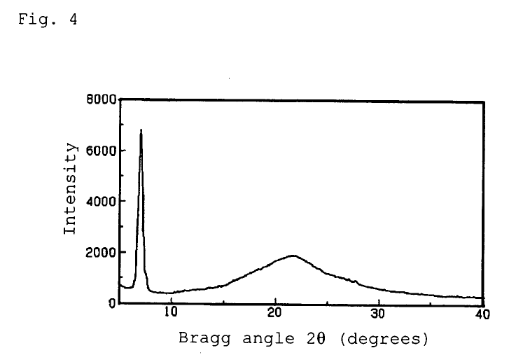

More specifically, FIG. 3 is a graph of an X-ray diffraction pattern of when a film of the tin phthalocyanine dichloride of the present invention is formed on an SiO₂ substrate (Bragg angle 2 θ=26.6°). FIG. 4 is a graph of an X-ray diffraction pattern of a copper phthalocyanine thin film (CuPc) on an SiO₂ substrate (comparative example). In FIG. 4, the maximum peak is at Bragg angle 2 θ=6.8° (interplanar spacing d=1.28 nm), and it is clear that the molecular plane is oriented substantially perpendicular to the substrate plane. The broad peak in the vicinity of 2 θ≈22°, however, is the peak for the underlying SiO₂ substrate.

FIGS. 4 and 5 in the above-mentioned Japanese Published Patent Application S63-244678 show the molecular plane of a lead phthalocyanine vapor deposited film being aligned parallel to the substrate plane. However, it has been reported that with a lead phthalocyanine vapor deposited film, 1) X-ray diffraction analysis reveals that triclinic crystals grow preferentially over monoclinic crystals near the surface, and this is distributed through the vapor deposited film, and 2) observation with an electron microscope reveals that a monoclinic vapor deposited film exhibits a heterogeneous structure in the film thickness direction (“Biodevice Research and Development Project,” Research and Development Association for Future Electron Devices (1996)). Thus, subsequent research has proven that the structure shown in FIGS. 4 and 5 of Japanese Published Patent Application S63-244678 is not accurate. Therefore, the actual structure of the organic semiconductor in the above publication is different from the active layer of the present invention.

Also, Japanese Published Patent Application H8-260146 discloses a thin film comprising a structure in which a rhenium atom is the central atom of a phthalocyanine ring, a nitrogen atom is triple-bonded to this rhenium atom, and the resulting rhenium phthalocyanine nitride molecules are stacked perpendicular to their molecular plane.

According to this publication (particularly column 3, lines 3 to 18), the substrate is not important as long as it allows phthalocyanine rings to be stacked in a vertical upwards direction on the substrate. But in actual fact interaction between the phthalocyanine rings and the substrate is necessary for phthalocyanine rings to be layered in a vertical upwards direction on the substrate, so it is stated that it is preferable to use an alkali halide substrate such as NaCl as the substrate. Also, this publication gives no examples of substrates other than NaCl or another such alkali halide substrate that allow phthalocyanine rings to be layered in a vertical upward direction on the substrate. Therefore, someone referring to this publication would conclude that an alkali halide substrate such as NaCl is used as the substrate and phthalocyanine rings are stacked in a vertical upwards direction, but since an alkali halide substrate such as NaCl is electrically insulating. Accordingly, phthalocyanine molecules could not be laminated on an electroconductive member such as a source electrode layer even by referral to this publication.

The inventors perfected the present invention upon discovering that the presence of ligands X₁ and X₂ that coordinate up and down, respectively, from the molecular plane of a phthalocyanine ring is essential to the stacking of phthalocyanine rings in a vertical upwards direction on the substrate. In contrast, Japanese Published Patent Application H8-260146 merely discloses that there is one nitrogen atom, via a triple bond, in the upward direction from the molecular plane of the phthalocyanine ring. Therefore, since Japanese Published Patent Application H8-260146 does not disclose the ligands X₁ and X₂ below and above the plane of a phthalocyanine ring, which were necessary to make the present invention, it would be extremely difficult to arrive at the present invention by referring to Japanese Published Patent Application H8-260146.

The thickness of the active layer can be suitably determined according to the composition, characteristics, and so forth of the active layer, but is usually at least 10 nm and no more than 200 nm, and it is particularly favorable to set it to a range of at least 30 nm and no more than 100 nm.

With the vertical organic FET of the present invention, the insulating layer 7 may be provided, as mentioned above, if the FET is an insulated gate type, for example. The material used for the insulating layer 7 may be suitably selected from among inorganic materials such as silicon oxide, silicon nitride, silicon oxynitride, or alumina, and organic materials such as polyethylene terephthalate, polyoxymethylene, polychloropyrene, polyvinyl chloride, polyvinylidene fluoride, cyanoethylpullulan, polycarbonate, polyimide, polysulfone, and polymethyl methacrylate.

Further, with the vertical organic FET of the present invention, the protective layer 6 can be provided as needed in order to protect against scratches or soiling or to improve storage stability. The protective layer 6 can be made from an inorganic material such as silicon oxide, or an organic material such as polymethyl acrylate, polycarbonate, epoxy resin, polystyrene, polyester resin, vinyl resin, cellulose, aliphatic hydrocarbon resin, natural rubber, wax, alkyd resin, dry oil, rosin, and other such heat-softening and heat-melting resins. A flame retardant, stabilizer, antistatic agent, or the like can also be added to the protective layer 6 as needed, and a thermosetting resin, photosetting resin, or the like may be used.

Also, with the present invention, a buffer layer made of an electron transport material, a hole transport material, FLiAl, or the like may be provided in order to achieve better contact between the active layer and the source electrode layer and/or drain electrode layer.

2. Method for Manufacturing a Vertical Organic FET

The present invention encompasses a method for manufacturing a vertical organic FET in which a source electrode layer, a drain electrode layer, a gate electrode, and an active layer are provided on a substrate, comprising a step of forming the active layer by using a phthalocyanine compound that has a tetravalent or hexavalent element as its central atom and has ligands X₁ and X₂, respectively, below and above the plane of the molecular of the compound which coordinate to the central atom.

The manufacturing method of the present invention is suited to the manufacture of vertical organic FETs of all types and all structures (laminated structures). It is particularly favorable for the manufacture of the vertical organic FET of the present invention. Especially, it is ideal for the manufacture of 1) a vertical organic FET in which an insulating layer is provided to the side wall of a laminate consisting of a source electrode layer, a drain electrode layer, and an active layer, so as to be in contact with these three layers, and a gate electrode is formed so as to be insulated from these three layers by the insulating layer (insulated gate type), and 2) a vertical organic FET in which an active layer and a gate electrode are interposed between a source electrode layer and a drain electrode layer, and the active layer and gate electrode are provided so as to be in contact with each other (Schottky gate type), for instance.

The manufacturing method of the present invention is particularly characterized in that a phthalocyanine compound having a tetravalent or hexavalent element is used as the central atom in the formation of an active layer. The phthalocyanine compound here is preferably one of those discussed in section 1. above.

The active layer can be formed from the phthalocyanine compound by a method that takes advantage of the sublimation, evaporation, or other properties of organic materials (more specifically, a vapor phase method such as vacuum vapor deposition, sputtering, or ion plating), as well as a liquid phase method such as coating. In particular, it is preferable with the manufacturing method of the present invention for the active layer to be formed by a vapor phase process using a phthalocyanine compound.

The conditions in the vapor phase process (and particularly vapor deposition) will vary with the type of phthalocyanine compound being used and other factors, but generally the substrate temperature is at least 20° C. and no higher than 100° C., the vapor deposition rate (film thickness increase rate) is at least 0.01 nm/sec and no more than 1 nm/sec, and the atmosphere is a vacuum (degree of vacuum: at least 1×10⁻⁶ Pa and no more than 8×10⁻³ Pa) When a vapor phase process is employed, the crystal system and orientation of the thin film of the phthalocyanine compound discussed above are dependent on the substrate temperature and other vapor deposition conditions, so during the production of the phthalocyanine thin film, the film production conditions may be optimized to obtain the desired characteristics. For instance, as reported in Thin Solid Films, 256 (1995), 64-67, and elsewhere, when the substrate temperature is 100° C. or higher, a triclinic thin film grows, but at room temperature, a monoclinic PbPc thin film grows, and the absorption spectra of these differ according to the orientation of the phthalocyanine molecules.

With the manufacturing method of the present invention, in addition to use the above-mentioned phthalocyanine compounds to form the active layer, a known vertical organic FET manufacturing method can also be followed. Therefore, the various electrodes 2 to 4 can be formed as desired by sputtering, vacuum vapor deposition, plating, or another such method. It is also possible to form the active layer by coating, electric field polymerization, or another such method from an electroconductive oligomer or an electroconductive polymer such as polyaniline, polypyrrole, or polythiophene.

### ADVANTAGES OF THE INVENTION

According to the present invention, since the active layer is formed from a specific phthalocyanine compound, the overlapping of π electrons in the phthalocyanine compound that makes up the active layer is vertical (that is, perpendicular to the substrate plane), so even with a vertical organic FET, better carrier mobility between the source electrode layer and drain electrode layer and better operating characteristics can be achieved.

### INDUSTRIAL APPLICABILITY

The vertical organic FET of the present invention can be used in a wide range of electronic devices, such as switching devices, light emitting diodes, non-linear optical devices, and field effect transistors.

### EXAMPLES

The features of the present invention will now be described in further detail by giving examples, but the scope of the present invention is not limited to or by these examples.

### Example 1

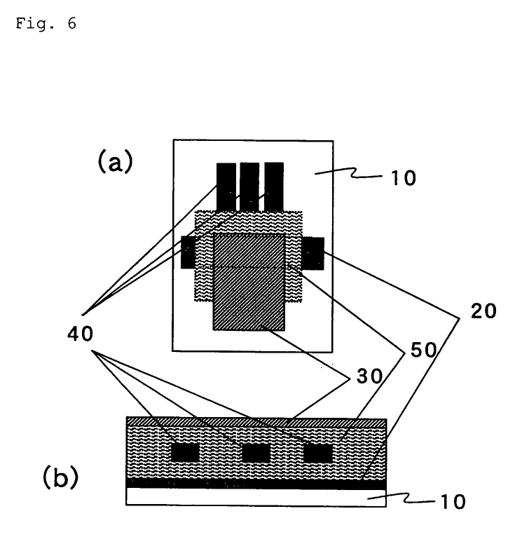

FIG. 6 illustrates a test example of the present invention. A film was formed in a thickness of 80 nm and a width of 1 mm from gold (source electrode layer 20) on a quartz substrate 10 by vacuum vapor deposition. A film of an organic compound (SnCl₂-Pc; active layer 50) was then formed in a thickness of 100 nm at a vapor deposition rate of 0.1 nm/sec, a substrate temperature of room temperature, and a degree of vacuum of 10⁻⁴ Pa. Then, aluminum was used to form gate electrodes 40 in a thickness of 50 nm and a spacing of 30 μm by vacuum vapor deposition, and this product was exposed to the air. After this, an active layer 50 was again formed in a thickness of 100 nm under the same conditions as above, over which gold (drain electrode layer 30) was vapor deposited in a thickness of 80 nm, which produced a vertical organic FET. The FET characteristics were evaluated under an inert atmosphere, the source and drain currents were modulated by gate voltage application, and the FET operation was checked.

Also, for the sake of comparison, a horizontal organic FET was produced in the same manner by vacuum vapor deposition. A silicon substrate was used, an insulating layer was formed over this substrate from SiO₂ by plasma CVD, a source electrode layer and drain electrode layer were formed over this from gold at a spacing of 500 μm, and an active layer was formed over this from SnCl₂-Pc under the same conditions as above, to produce a horizontal organic FET. This horizontal organic FET was evaluated, but there was almost no modulation seen in the source and drain currents under gate voltage application of several tens volts, which confirmed that the molecular orientation of the present invention is effective in a vertical organic FET.

Also, in addition to using the above-mentioned organic compound (SnCl₂-Pc) as the material constituting the active layer, films were also produced by vacuum vapor deposition from SnBr₂-Pc, SnI₂-Pc, SnPh₂-Pc, and MeSiCl-Pc, vertical organic FETs were produced in the same manner as above, and their operation was evaluated. In every case, the source and drain currents were modulated by gate voltage.

The X-ray diffraction patterns of the active layers produced on quartz substrates were also evaluated at the same time. The X-ray diffraction peaks were as follows: SnBr₂-Pc (2 θ=27.1°), SnI₂-Pc (2 θ=27.0°), SnPh₂-Pc (2 θ=26.4°), MeSiCl-Pc (2 θ=26.0°), and SnCl₂-Pc (2 θ=26.6°).

### INDUSTRIAL APPLICABILITY

As discussed above, the vertical organic FET of the present invention has excellent operating speed because the orientation of its molecules is controlled according to its vertical configuration, and also allows devices to be mass-produced easily and at low cost.

1. A vertical organic FET having a structure in which at least a source electrode layer, a drain electrode layer, a gate electrode, and an active layer are provided on a substrate, and the source electrode layer, the active layer, and the drain electrode layer are laminated in that order, wherein:
(1) the source electrode layer and the drain electrode layer are disposed substantially parallel to the substrate plane;
(2) the source electrode layer and the drain electrode layer comprises conductive material, respectively;
(3) the active layer is substantially constituted by a phthalocyanine compound that has a tetravalent or hexavalent element as its central atom and has ligands X₁ and X₂, respectively, below and above the plane of the molecular of the compound which coordinate to the central atom; and
(4) the compound is layered so that the plane of each molecule of the compound is in a substantially parallel state with respect to the source electrode layer and/or the drain electrode layer.

2. The vertical organic FET according to claim 1, wherein the compound is layered so that, as the parallel state, the angle formed by the molecular plane and the substrate plane is in the range of no less than 0 degrees but no more than 45 degrees.

3. The vertical organic FET according to claim 1, wherein, in an X-ray diffraction pattern obtained by analyzing the active layer with X-ray diffraction using a Cu—Kα radiation, the diffraction peak having the greatest intensity appears in the region where the Bragg angle (2 θ) is at least 20°.

4. The vertical organic FET according to claim 1, wherein, in an X-ray diffraction pattern obtained by analyzing the active layer with X-ray diffraction using a Cu—Kα radiation, the diffraction peak having the greatest intensity appears in the region where the Bragg angle (2 θ) is no less than 25.5° but no more than 27.5°.

5. The vertical organic FET according to claim 1, wherein the central atom is a tetravalent element.

6. The vertical organic FET according to claim 1, wherein the central atom is Si, Ge, or Sn.

7. The vertical organic FET according to claim 1, wherein the phthalocyanine compound is represented by the following general formula: 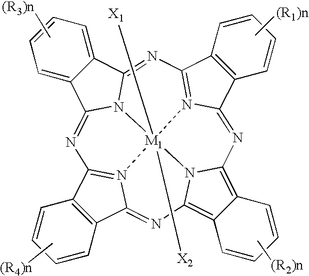
wherein R₁ to R₄ may be the same or different, and are each a hydrogen or a substituent; n is the number of substituents; M1 is Si, Ge, or Sn; X₁ and X₂ may be the same or different, and are each a halogen, phenyl group, or C₅ or lower alkyl group.

8. The vertical organic FET according to claim 1, wherein the conductive material is at least one type selected from among metals, metal oxides, and silicon.

9. The vertical organic FET according to claim 1, wherein an insulating layer is provided on a side of the laminate composed of the source electrode layer, the drain electrode layer, and the active layer so as to be in contact with these three layers, and the gate electrode is formed so as to be insulated from the three layers by the insulating layer.

10. The vertical organic FET according to claim 1, wherein the active layer and the gate electrode are interposed between the source electrode layer and the drain electrode layer, and the active layer and gate electrode are provided so as to be in contact with each other.

11. A vertical organic FET having a structure in which at least a source electrode layer, a drain electrode layer, a gate electrode, and an active layer are provided on a substrate, and the source electrode layer, the active layer, and the drain electrode layer are laminated in that order, wherein:
(1) the source electrode layer and the drain electrode layer are disposed substantially parallel to the substrate plane;
(2) the source electrode layer and the drain electrode layer comprises conductive material, respectively;
(3) the active layer is substantially constituted by a phthalocyanine compound that has a tetravalent or hexavalent element as its central atom and has ligands X₁ and X₂, respectively, below and above the plane of the molecular of the compound which coordinate to the central atom; and
(4) in an X-ray diffraction pattern obtained by analyzing the active layer with X-ray diffraction using a Cu—Kα radiation, the diffraction peak having the greatest intensity appears in the region where the Bragg angle (2 θ) is at least 20°.

12. The vertical organic FET according to claim 11, wherein the diffraction peak appears in the region where the Bragg angle (2 θ) is no less than 25.5° but no more than 27.5° C.

13. The vertical organic FET according to claim 11, wherein the central atom is a tetravalent element.

14. The vertical organic FET according to claim 11, wherein the central atom is Si, Ge, or Sn.

15. The vertical organic FET according to claim 11, wherein the phthalocyanine compound is represented by the following general formula: 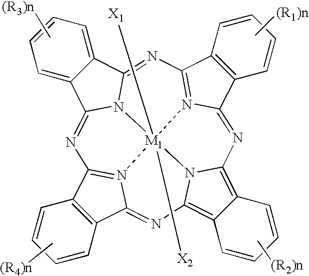
wherein R₁ to R₄ may be the same or different, and are each a hydrogen or a substituent; n is the number of substituents; M1 is Si, Ge, or Sn; X₁ and X₂ may be the same or different, and are each a halogen, phenyl group, or C₅ or lower alkyl group.

16. The vertical organic FET according to claim 11, wherein the conductive material is at least one type selected from among metals, metal oxides, and silicon.

17. The vertical organic FET according to claim 11, wherein an insulating layer is provided on a side of the laminate composed of the source electrode layer, the drain electrode layer, and the active layer so as to be in contact with these three layers, and the gate electrode is formed so as to be insulated from the three layers by the insulating layer.

18. The vertical organic FET according to claim 11, wherein the active layer and the gate electrode are interposed between the source electrode layer and the drain electrode layer, and the active layer and gate electrode are provided so as to be in contact with each other.

19. A method for manufacturing a vertical organic FET in which a source electrode layer, a drain electrode layer, a gate electrode, and an active layer are provided on a substrate,
comprising a step of forming the active layer by using a phthalocyanine compound that has a tetravalent or hexavalent element as its central atom and has ligands X₁ and X₂, respectively, below and above the plane of the molecular of the compound which coordinate to the central atom.

20. The manufacturing method according to claim 19, wherein the central atom is a tetravalent element.

21. The manufacturing method according to claim 19, wherein the central atom is Si, Ge, or Sn.

22. The manufacturing method according to claim 19, wherein the phthalocyanine compound is represented by the following general formula: 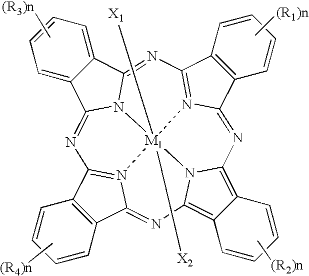
wherein R₁ to R₄ may be the same or different, and are each a hydrogen or a substituent; n is the number of substituents; M₁ is Si, Ge, or Sn; X₁ and X₂ may be the same or different, and are each a halogen, phenyl group, or C₅ or lower alkyl group.

23. The manufacturing method according to claim 19, wherein the active layer is formed by vapor phase process using the phthalocyanine compound.

24. The manufacturing method according to claim 19, wherein the vertical organic FET is one having a structure in which at least a source electrode layer, a drain electrode layer, a gate electrode, and an active layer are provided on a substrate, and the source electrode layer, the active layer, and the drain electrode layer are laminated in that order, wherein:
(1) the source electrode layer and the drain electrode layer are disposed substantially parallel to the substrate plane;
(2) the source electrode layer and the drain electrode layer comprises conductive material, respectively;
(3) the active layer is substantially constituted by a phthalocyanine compound that has a tetravalent or hexavalent element as its central atom and has ligands X₁ and X₂, respectively, below and above the plane of the molecular of the compound which coordinate to the central atom; and
(4) the compound is layered so that the plane of each molecule of the compound is in a substantially parallel state with respect to the source electrode layer and/or the drain electrode layer.

25. The manufacturing method according to claim 19, wherein the vertical organic FET is one having a structure in which at least a source electrode layer, a drain electrode layer, a gate electrode, and an active layer are provided on a substrate, and the source electrode layer, the active layer, and the drain electrode layer are laminated in that order, wherein:
(1) the source electrode layer and the drain electrode layer are disposed substantially parallel to the substrate plane;
(2) the source electrode layer and the drain electrode layer comprises conductive material, respectively;
(3) the active layer is substantially constituted by a phthalocyanine compound that has a tetravalent or hexavalent element as its central atom and has ligands X₁ and X₂, respectively, below and above the plane of the molecular of the compound which coordinate to the central atom; and
(4) in an X-ray diffraction pattern obtained by analyzing the active layer with X-ray diffraction using a Cu—Kα radiation, the diffraction peak having the greatest intensity appears in the region where the Bragg angle (2 θ) is at least 20°.
